(19) United States
(12) Patent Application Publication
(10) Pub. No.: US 2004/0027477 A1
(43) Pub. Date: Feb. 12, 2004

(54) Camera module and method for manufacturing the same

(76) Inventors: Hiroyuki Tamura, Gunma (JP); Kenichi Kobayashi, Gunma (JP)

Correspondence Address: FISH & RICHARDSON P.C., 45 ROCKEFELLER PLAZA, SUITE 2800, NEW YORK, NY, 10111, US

(21) Appl. No.: 10/462,999

(22) Filed: Jun. 17, 2003

(30) Foreign Application Priority Data
Jun. 28, 2002 (JP) P. 2002-190794
Jul. 16, 2002 (JP) P.2002-207454
May 27, 2003 (JP) P.2003-149201

(51) Int. Cl. H04N 5/225

(52) U.S. Cl. 348/340

(57) ABSTRACT

CCD 15 and peripheral elements 16 are mounted on the surface of a mount portion 11B of a flexible sheet 11, and a circuit device 20 is mounted on the back surface of the mount portion 11B. DSP and a driver IC are installed in the circuit device 20, and the circuit device 20 is electrically connected to CCD 15 through electrical conductive paths 11E formed in the flexible sheet 11. CCD 15 and the peripheral elements 16 mounted on the mount portion 11B are covered by a lens mount 12. Accordingly, a camera module which is unified with the flexible sheet 11 is provided.

### BACKGROUND OF THE INVENTION

1. Field of the Invention

The present invention relates to a camera module and a method for manufacturing the same, and particularly to a camera module which can be reduced in thickness by unifying a resin sheet and a circuit device into one body.

2. Description of the Related Art

Recently, camera modules have been positively used in cellular phones, mobile computers, etc. Therefore, it has been strongly required that the camera modules are designed to be compact in size, small in thickness and light in weight. In the present invention, a camera module using a CCD as an image pickup device will be described as an embodiment. However, the present invention may be applied to a camera module using an image pickup device other than a CCD (for example, CMOS sensor or the like).

FIG. 26 shows the structure of a conventional camera module 100.

First, CCD 102 is mounted on a mount board 101, and a lens 105 for converging light from the exterior is fixed to a lens barrel 106 at the upper side of CCD 102. The lens barrel 106 is held by a lens mount 107, and the lens mount 107 is mounted on the mount board 101 by lens fixing screws 108. Furthermore, a flexible sheet 120 is fixed onto the mount board 101 through a connecting means 121.

Here, CCD, which stands for Charge Coupled Device, works to output the charges corresponding to the intensity of light converged by the lens 105. The lens barrel 106 has a threaded side surface (not shown), and it is rotated to bring the lens 105 into focus.

Furthermore, chip elements 103 and back-surface chip elements 104 are mounted on the surface and back surface of the mount board 101, respectively. These chips contain DSP, a driving IC, capacitors, resistors, diodes, etc. DSP, which stands for Digital Signal Processor, works to process digital signals transmitted from CCD 102 at high speed. The driving IC increases the voltage of the driving signal from DSP to drive CCD 102 and transfers the charges accumulated in CCD 102.

Referring to FIG. 26B, the flexible sheet 120 is electrically connected to the mount board 101 through the connecting means 121 such as solder which is provided at the peripheral portion of the mount board 101. A connector is exposed at the other end portion of the flexible sheet, and the camera module 100 and the exterior are electrically connected to each other through the connector.

A method for fabricating the camera module 100 will be described with reference to FIGS. 27A, 27B and 27C.

Referring to FIG. 27A the mount board 101 is prepared, and the back-surface chip elements 104 are mounted on the back surface of the mount board 101. Electrical conductive paths are formed on the back surface of the mount board 101, and the back-surface chip elements 104 are mounted in the electrical conductive paths through brazing material such as solder. The respective conductive parts formed on both surfaces of the mount board 101 may be electrically connected to one another through via holes (not shown) which are formed so as to penetrate through the mount board.

Referring to FIG. 27B, CCD 102 and the chip elements 103 are mounted on the surface of the mount board 101. Electrical conductive paths are formed on the surface of the mount board 101, and CCD 102 and the chip elements 103 are electrically mounted on the electrical conductive paths through brazing material such as solder.

Finally, referring to FIG. 27C, the lens barrel 106 to which the lens 105 is fixed is fixedly mounted on the lens mount 107, and the lens mount 107 is fixed on the mount board 101 by using the lens fixing screws 108. In order to fix the lens mount 107 by the lens fixing screws 108, screw holes 110 are needed at corresponding positions. Furthermore, the flexible sheet is connected to the peripheral portion of the mount board 101 through the connecting means 121. According to the above-described method, the conventional camera module 100 using the mount board 101 is completed.

However, the camera module as described above has the following problems.

First, the chip elements 103, the back-surface chip elements 104, the lens 105, the lens barrel 106, the lens mount 107 and CCD 102 are indispensable constituent elements. However, it has been difficult for only these elements to provide a camera module, which can perform miniaturization and reduction in thickness and weight.

Second, when a conventional module 100 is mounted in the housing of a set such as a digital camera, the mount structure becomes complicated because both surfaces of the camera module 100 are not flat.

Third, the respective elements constituting the camera module 100 are individually mounted on the electrical conductive paths formed on the mount board 101. Accordingly, when connectors of a flexible sheet for drawing wires are required to be altered, design changes are required to be carried out on the electrical conductive paths on the mount board 101.

Fourth, there is a predisposition where extracting electrodes of an IC are designed so that the number of pins is increased and the pitch thereof is reduced, and in order to meet this tendency, the mount board 101 is required to have a multi-layered wiring structure including about four layers. This causes an increase in the cost of camera modules.

### SUMMARY OF THE INVENTION

The present invention has been implemented in view of the foregoing situation, and has an object to provide a compact and light camera module integrated with a resin sheet, and a method for manufacturing the camera module.

In order to attain the above object, according to the present invention, a camera module is provided which comprises a resin sheet having electrical conductive paths on both surfaces thereof; a lens mount provided on the surface of the resin sheet; a circuit device mounted on the back surface of the resin sheet; an image pickup device mounted in the lens mount; and a lens fixed to the upper portion of the lens mount, wherein the circuit device contains a semiconductor device electrically connected to the image pickup device and a passive element.

According to the present invention, a method for manufacturing a camera module is provided which comprises the steps of: preparing a resin sheet having a mount portion formed at one end thereof, the mount portion having electrical conductive paths on both surfaces thereof; mounting a circuit device on connection electrodes on the back surface of the mount portion; mounting an image pickup device on connection electrodes on the surface of the mount portion; and mounting a lens mount so as to cover the image pickup device.

The present invention has the following effects.

First, in the camera module 10 of the present invention, CCD 15, etc., are mounted on the surface of the flexible sheet 11 as the resin sheet, and the circuit device 20 is mounted on the back surface of the flexible sheet 11. Furthermore, the semiconductor 22A and the chip elements 22B are installed in the circuit device 20. Accordingly, most of the functions required for the camera module are systematized in the circuit device 20, so that the wiring structure of the flexible sheet 11 can be simplified. Furthermore, the back surface of the flexible sheet 11 which is opposite to the CCD 15 mount surface becomes a resin surface of the circuit device 20 which is formed to be flat. Accordingly, the camera module 10 can be mounted by merely making the resin surface adhere to the inside of the housing via insulating adhesive agent or the like.

Second, both the circuit device 20 and the flexible sheet 11 can be designed in the multi-layered wiring structure, so that they can be designed as a unified body when the patterns are formed. Accordingly, elements to be mounted can be optimized, and the layer structures of the circuit device and the flexible sheet 11 can be optimized.

Third, CCD 15 and the peripheral elements 16 mounted on the surface of the mount portion 11B of the flexible sheet are covered by the lens mount 12. Accordingly, the camera module 10 has a structure having no projecting part, thereby facilitating the mechanical design of digital cameras, cellular phones having a camera mechanism function or the like in which the camera module 10 is mounted.

Fourth, the layer structure of the flexible sheet 11 can be simplified by using the circuit device 20. Therefore, even when the arrangement of the connectors 11A is required to be changed, the requirement can be flexibly satisfied by merely changing the wire structure of the flexible sheet 11.

Fifth, the function level of the camera module 10 can be changed by changing only the circuit device 20. Concretely, a plurality of kinds of circuit devices 20 containing elements different in function level are prepared. In accordance with a required function level, the circuit device 20 satisfying the function level thus required is mounted on the flexible sheet 11. Accordingly, the function level of the camera module 10 can be easily changed.

Sixth, the specification of the camera module 10 can be changed by merely mounting CCD l5 whose number of pixels satisfies a required number of pixels, on connection electrodes 11C of the flexible sheet 11.

Seventh, in place of CCD 15, a CMOS sensor may be used as an image pickup device to be mounted on the flexible sheet 11. When the CMOS sensor is used, semiconductor devices having functions other than DSP and the driver IC may be used as elements to be installed in the circuit device 20. For example, a semiconductor element having a moving image compressing function and a USB interface function may be installed in the circuit device 20.

Eighth, the mechanical strength of the mount portion 11B can be enhanced by mounting the circuit device 20 on the back surface of the mount portion 11B of the flexible sheet 11, thereby enhancing the overall strength of the camera module. Furthermore, the reduction in mounting precision due to bending of the mount portion 11B comprising the flexible sheet 11 can be prevented in the step of mounting elements such as CCD 15, on the surface of the mount portion 11B.

Ninth, in the present invention, elements such as CCD 15, are mounted on the surface of the mount portion 11B of the flexible sheet 11, and the circuit device 20 mounted on the back surface of the mount portion 11B is a thin type package article. Furthermore, the camera module of the present invention has the structure excluding a mount board required in the prior art. Accordingly, the camera module 10 is designed to be very small in size and thickness and light in weight.

### BRIEF DESCRIPTION OF THE DRAWINGS

FIG. 1A is a perspective view showing a camera module according to the present invention, FIG. 1B is a perspective view showing the circuit device used in the camera module and FIG. 1C is a cross-sectional view showing the camera module;

FIG. 2A is a perspective view showing the camera module according to the present invention, and FIG. 2B is across-sectional view showing the camera module according to the present invention;

FIG. 3A is a perspective view showing the camera module according to the present invention, and FIG. 3B is a cross-sectional view showing the camera module according to the present invention;

FIG. 4 is a cross-sectional view showing the camera module according to the present invention;

FIG. 5A is a cross-sectional view showing the camera module according to the present invention, and FIG. 5B is a cross-sectional view showing the camera module according to the present invention;

FIG. 6A is a perspective view showing a lens mount used in the camera module according to the present invention, FIG. 6B is a back side view of the lens mount according to the present invention, and FIG. 6C is a cross-sectional view showing the lens mount according to the present invention;

FIG. 7A is a plan view showing a flexible sheet used in the camera module according to the present invention, and FIG. 7B is a plan view of the flexible sheet according to the present invention;

FIG. 8A is a plan view showing the flexible sheet used in the camera module according to the present invention, and FIG. 8B is a plan view of the flexible sheet according to the present invention;

FIG. 9A is a plan view showing a circuit device used in the camera module according to the present invention, and FIG. 9B is a cross-sectional view of the circuit device according to the present invention;

FIG. 10 is a cross-sectional view showing the circuit device used in the camera module according to the present invention;

FIG. 11A is a plan view showing the circuit device used in the camera module according to the present invention, and FIG. 11B is a plan view showing the circuit device according to the present invention;

FIG. 12 is a process diagram showing a method for manufacturing the camera module according to the present invention;

FIG. 13A is a cross-sectional view showing the method for manufacturing the camera module according to the present invention, and FIG. 13B is a plan view showing the camera module manufacturing method according to the present invention;

FIG. 14 is a cross-sectional view showing the camera module manufacturing method according to the present invention;

FIG. 15 is a plan view showing the camera module manufacturing method according to the present invention;

FIG. 16A is a plan view showing the camera module manufacturing method according to the present invention, and FIG. 16B is a cross-sectional view showing the camera module manufacturing method according to the present invention;

FIG. 17A is a cross-sectional view showing the camera module manufacturing method according to the present invention, and FIG. 17B is a plan view showing the camera module manufacturing method according to the present invention;

FIG. 18 is a plan view showing the camera module manufacturing method according to the present invention;

FIG. 19A is a cross-section view showing the camera module manufacturing method according to the present invention, FIG. 19B is a cross-sectional view showing the camera module manufacturing method according to the present invention, and FIG. 19C is a cross-sectional view showing the camera module manufacturing method according to the present invention;

FIG. 20 is a cross-sectional view showing the camera module manufacturing method according to the present invention;

FIG. 21 is a cross-sectional view showing the camera module manufacturing method according to the present invention;

FIG. 22 is a cross-sectional view showing the camera module manufacturing method according to the present invention;

FIG. 23 is a cross-sectional view showing the camera module manufacturing method according to the present invention;

FIG. 24 is a cross-sectional view showing the camera module manufacturing method according to the present invention;

FIG. 25 is a cross-sectional view showing the camera module manufacturing method according to the present invention;

FIG. 26A is a cross-sectional view showing a conventional camera module, and FIG. 26B is a plan view showing the conventional camera module; and

FIG. 27A is a cross-sectional view showing the conventional camera module, FIG. 27B is a cross-sectional view showing the conventional camera module, and FIG. 27C is a cross-sectional view showing the conventional camera module.

### DETAILED DESCRIPTION OF THE PREFERRED EMBODIMENTS

(First Embodiment for Structure of Camera Module 10)

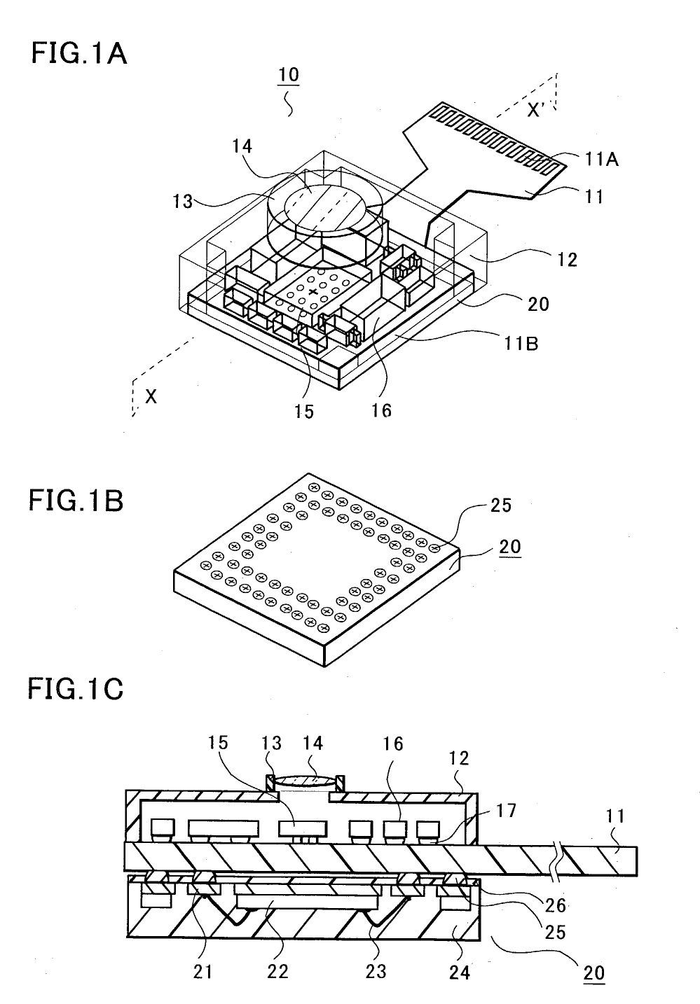

The structure of a camera module 10 according to the present invention will be described with reference to FIG. 1A through FIG. 1C. FIG. 1A is a perspective view showing the camera module 10, FIG. 1B is a perspective view showing a circuit device 20 and FIG. 1C is a cross-sectional view taken along the X-X′ line of FIG. 1A.

Referring to FIG. 1A, the camera module has the following structure. That is, the camera module 10 comprises a flexible sheet 11 as a resin sheet having electrical conductive paths on both surfaces thereof, a lens mount 12 equipped on the surface of the flexible sheet 11, a circuit device 20 mounted on the back surface of the flexible sheet 11, CCD 15 as an image pickup device installed in the lens mount 12 and a lens 14 fixed to the upper portion of the lens mount 12, wherein the circuit device 20 contains a semiconductor element electrically connected to the image pickup device and a passive element.

Referring to FIG. 1A, a plurality of connectors 11A to be electrically connected to the exterior are formed at one end of the flexible sheet 11 as the resin sheet, and a mount portion 11B in which CCD 15, etc., constituting the camera module are mounted is formed at the other end of the flexible sheet 11. The one end portion of the flexible sheet 11 on which the connectors 11A are formed is designed to be larger in width than the intermediate portion of the flexible sheet 11. CCD 15 and peripheral elements 16 are formed on the surface of the mount portion 11B, and thus electrodes are formed at these places. Furthermore, the circuit device 20 is mounted on the back surface of the mount portion 11B, and thus electrodes are formed at places corresponding to the electrodes of the circuit device 20. The flexible sheet 11 may be constructed by multi-layered wires.

CCD 15 is a semiconductor image pickup device, and it is fixed on the surface of the flexible sheet 11. The planar position of CCD 15 is fixed to be located below the lens 14. CCD 15 works to convert light converged by the lens 14 into an electrical signal, and outputs the charges corresponding to the light amount of light incident thereto. A chip set containing DSP, a driver IC, etc., for performing the signal processing of CCD 15 and the driving of CCD 15 is contained in the circuit device 20 fixed on the back surface of the flexible sheet 11. The chip set containing DSP, the driver IC, etc., and CCD 15 are electrically connected to each other through wires formed on the flexible sheet 11. In place of CCD, a CMOS sensor may be used as the image pickup device.

The following description will be made in a case where the present invention is applied to CCD 15. However, the same effect may be achieved when a CMOS sensor is used as the image pickup device.

Referring to FIG. 1B, the circuit device 20 is fixed on the back surface of the mount portion 11B of the flexible sheet 11 through external electrodes 25 formed of brazing material such as solder. In the circuit device 20 are mounted DSP for carrying out the processing of electrical signals from CCD 15, the driver IC for driving CCD 15, etc. Furthermore, in the circuit device 20, passive elements such as chip resistors, capacitors, as well as the semiconductor device are contained. The circuit device 20 is different from CSP or the like which has been conventionally used, and it is designed as a thin type which does not require any mount board. In FIG. 1B, the circuit device 20 is illustrated with the external electrodes 25 placed face up, and electrodes are provided at the positions corresponding to the external electrodes 25 on the back surface of the mount portion 11B of the flexible sheet 11. A detailed structure of the circuit device 20 will be described later. Referring to FIG. 1C, the circuit device 20 is mounted on the flexible sheet with the external electrodes 25 placed face up, and a flat face formed of insulating resin is formed on the surface opposite to the surface on which the external electrodes 25 are formed. Accordingly, the flat face makes it easy to mount a camera or the like into the housing.

Referring to FIG. 1A and FIG. 1C, the lens mount 12 is mounted at the peripheral portion on the surface of the mount portion 11B of the flexible sheet 11 via an insulating adhesive agent or the like. CCD 15 and the peripheral elements 16 mounted on the mount portion 11B are covered by the lens mount 12. The shape of the lens mount 12 is designed as a hollow structure, and a hole through which light converged by the lens 14 is passed is formed in the vicinity of the center on the upper surface of the lens mount 12. Furthermore, by forming step portions at the peripheral portions of the lens mount 12 which abut against the mount portion 11B, the lens mount 12 can be designed so that the mount portion 11B and the circuit device 20 are engageable with the peripheral portions.

The mount portion 11B of the flexible sheet 11, the circuit device 20 and the lens mount 12 are formed so as to be equal in two-dimensional size. As described above, the lens mount 12 is fixed to the surface of the mount portion 11B equipped to the end portion of the flexible sheet 11, and the circuit device 20 is mounted on the back surface of the mount portion 11B. Accordingly, the mount portion 11B, the circuit device 20 and the lens mount 12 are overlaid upon one another, and the outer shape of the camera module 10 is designed to be compact and has no projecting part.

Referring to FIG. 1A and FIG. 1C, the lens 14 is fixed via the insulating adhesive agent to the lens barrel 13 equipped to the upper portion of the lens mount l2. The two-dimensional position of the lens 14 accurately corresponds to the two-dimensional position of CCD 15 located below the lens 14. A hole is formed in the lens mount 12 at the lower side of the lens 14. Accordingly, light incident to the lens 14 is accurately converged to the photoreception portion of CCD 15. Furthermore, the lens barrel 13 and the lens mount 12 are joined to each other by a screw structure. Accordingly, they can be coupled to each other while adjusting the focus point of the lens 14.

Here, the difference in the role between the circuit element 22 contained in the circuit device 20 and the peripheral elements 16 mounted on the surface of the mount portion 11B of the flexible sheet 11 will be described.

The circuit element 22 contained in the circuit device 20 carries out the output signal processing of CCD 15 and the driving of CCD 15. Concretely, DSP for carrying out the signal processing, a semiconductor device 22A, etc., are adopted. Capacitors, resistors, coils, etc., which mainly act as countermeasures to noises are adopted as the peripheral elements 16 mounted on the surface of the mount portion 11B.

An advantage achieved by making the role different between the circuit element 22 and the peripheral elements 16 as described above will be described. For example, when the output from the camera module 10 has an intense noise, the circuit device 20 can be directly used by merely altering the peripheral elements 16. That is, a main function chip is installed in the circuit device 20, and the peripheral elements 16 for reducing noises are mounted on the surface of the mount portion 11B of the flexible sheet 11, whereby the characteristics can be enhanced by merely altering the peripheral elements 16.

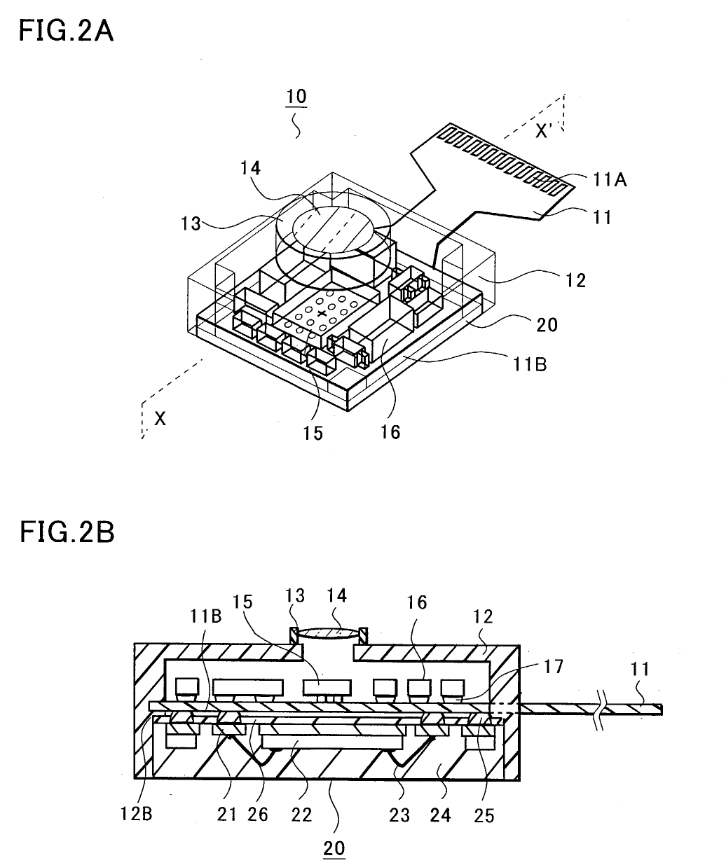

The structure of the camera module 10 according to another embodiment will be described with reference to FIG. 2A and FIG. 2B. FIG. 2A is a perspective view showing the camera module 10, and FIG. 2B is a cross-sectional view taken along X-X′ of FIG. 2A. The basic structure of the camera module 10 shown in FIG. 2A and FIG. 2B is similar to that shown in FIG. 1A through FIG. 1C, however the difference resides in the structure of the lens mount 12.

In this embodiment, the lens mount 12 covers the mount portion 11B of the flexible sheet 11 and the side surface of the circuit device 20. Accordingly, the lens mount 12 and the circuit device 20 are directly fixed to each other, so that the positional precision in the horizontal direction between CCD 15 and the lens 14 can be enhanced. Furthermore, contact portions 12B are equipped at the four corners of the inside of the lens mount 12 to bring the contact portions 12B and the circuit device 20 into contact with each other, thereby enhancing the positional precision in the vertical direction between CCD 15 and the lens 14.

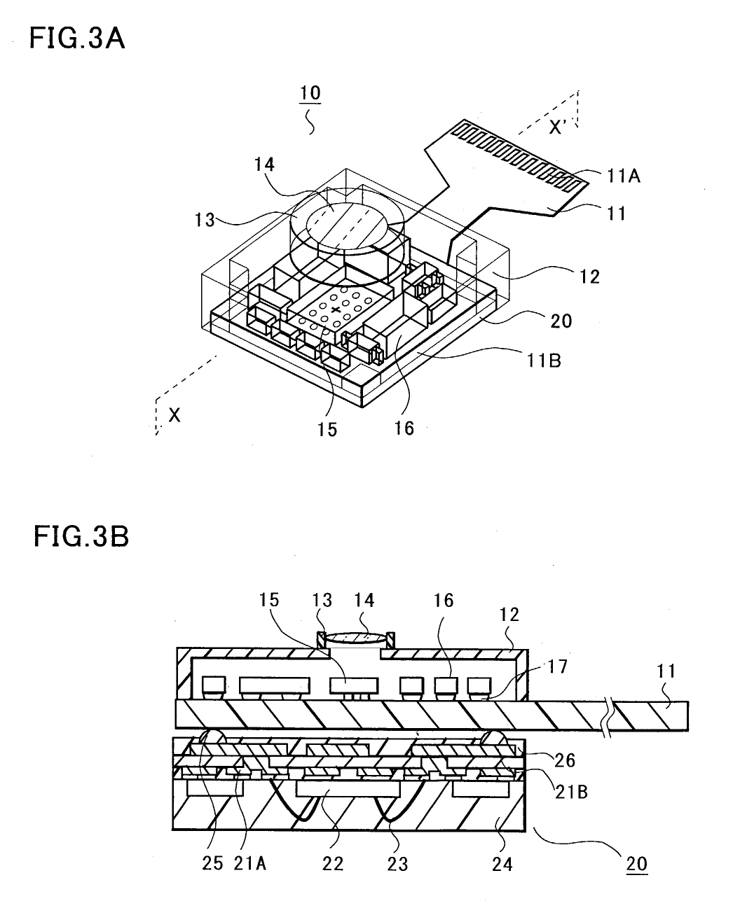

The structure of the camera module according to another embodiment will be described with reference to FIG. 3A and FIG. 3B. FIG. 3A is a perspective view showing the camera module 10, and FIG. 3B is a cross-sectional view taken along X-X′ of FIG. 3A. The basic structure of the camera module 10 shown in FIG. 3A and FIG. 3B is similar to that shown in FIG. 1A through FIG. 1C, however the difference resides in the structure of the circuit device 20.

In this embodiment, the circuit device 20 has a multi-layered wire structure. Concretely, the circuit device has a multi-layered wire structure including two layers of a first conductive pattern 21A and a second conductive pattern 21B. With the multi-layered wire structure, even when the circuit element installed is a multiple-pin type semiconductor device, it can be supported by constructing a minute conductive pattern with the first conductive pattern 21A. Details of the multi-layered circuit device 20 will be described later.

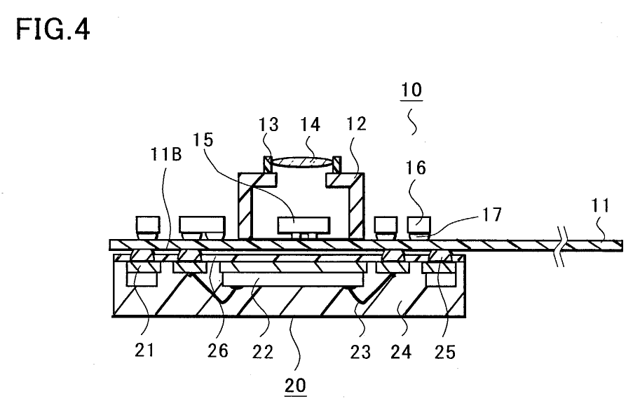

The structure of the camera module according to another embodiment will be described with reference to FIG. 4. FIG. 4 is a cross-sectional view showing the camera module 10. The basic structure of the camera module shown in FIG. 4 is similar to that shown in FIG. 1A through FIG. 1C, however the difference resides in the structure of the lens mount 12.

In this embodiment, the lens mount 12 contains only CCD 15. Accordingly, the camera module 10 having a simplified structure can be provided. Furthermore, here, the circuit device 20 is designed in a monolayer wire structure, however, it may be designed in a multi-layered wire structure.

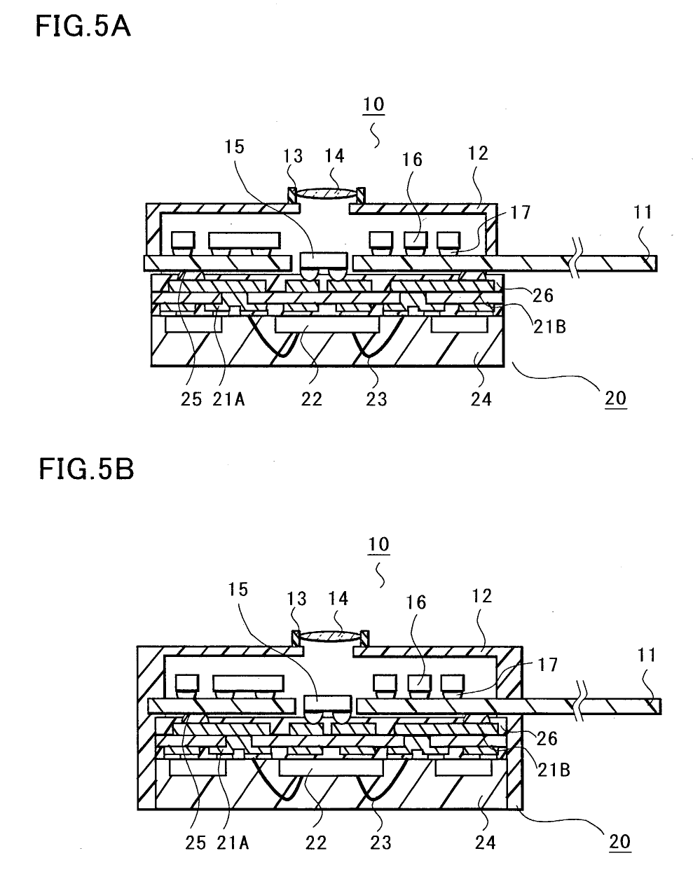

The structure of the camera module 10 according to other embodiments will be described with reference to FIG. 5A and FIG. 5B. FIG. 5A and FIG. 5B are cross-sectional views showing the camera modules 10 of different embodiments. The basic structure of the camera modules 10 shown in FIG. 5A and FIG. 5B are similar to that shown in FIG. 1A through FIG. 1C, however the difference resides in the connection structure of CCD 15 as an image pickup device.

Concretely, referring to FIG. 5A, an opening portion is formed in an area of the flexible sheet 11 on which CCD 15 will be mounted, and CCD 15 is mounted on the conductive pattern of the circuit device 20 exposed from the opening portion. In this embodiment, the circuit device 20 has a multi-layered wire structure, and CCD 15 is fixed on the back surface of the second conductive pattern 21B exposed to the back surface (upper surface). Accordingly, as compared with the case where CCD 15 is mounted on the flexible sheet 11, the mounting precision of CCD 15 can be further enhanced.

Referring to FIG. 5B, the lens mount 12 covers the side surface of the circuit device 20 in the camera module shown in FIG. 5B. Accordingly, the positional precision between the lens mount 12 to which the lens 14 is fixed and the circuit device 20 is enhanced. Furthermore, CCD 15 is also fixed to the circuit device 20, and thus the positional precision between CCD 15 and the lens mount 12 can be enhanced.

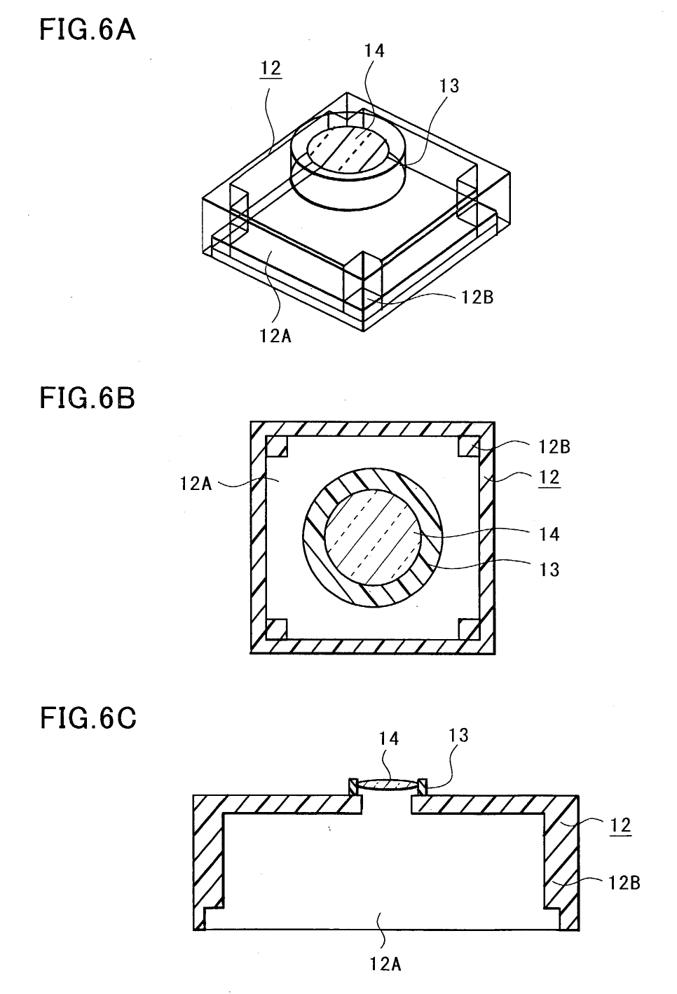

Details of the lens mount 12 used in the camera module 10 will be described with reference to FIG. 6A through FIG. 6C. FIG. 6A is a perspective view showing the lens mount 12, FIG. 6B is aback-side view of the lens mount l2, and FIG. 6C is a cross-sectional view of the lens mount 12.

Referring to FIG. 6A, the lens mount 12 has a hollow structure, and the lens 14 is fixed to the upper portion of the lens mount 12 through the lens barrel 13. The overall shape of the lens mount 12 is a rectangular parallelepiped, and the lens barrel 13 to which the lens 14 is fixed is provided on the upper portion of the lens mount 12.

Referring to FIG. 6B, the lens mount 12, which has a hollow structure, has an opening portion 12A at the lower portion thereof, and contact portions 12B are formed at the four corners of the opening portion. The contact portions 12B are brought into direct contact with the circuit device 20 via insulating adhesive agent or the like. In this embodiment, four contact portions 12B are formed at the four corner portions of the inner wall of the lens mount 12, and the number of contact portions 12B and the locations thereof may be changed as occasion demands. Furthermore, the two-dimensional size of the opening portion 12A is set to the same size as the circuit device 20 and the mount portion 11B of the flexible sheet 11 which are accommodated at this place.

Referring to FIG. 6C, the lower surfaces of the contact portions 12B are located at higher positions than the lower surface of the lens mount 12. The distance between the lower surface of each contact portion 12B and the lower surface of the lens mount 12 may be set to be equal to or less than the thickness of the circuit device 20. Accordingly, by bringing the circuit device 20 into contact with the contact portions 12B, the side surface portion of the circuit device 20 abuts against the inner surface of the lens mount 12, and the circuit device 20 and the lens mount 12 are firmly joined to each other.

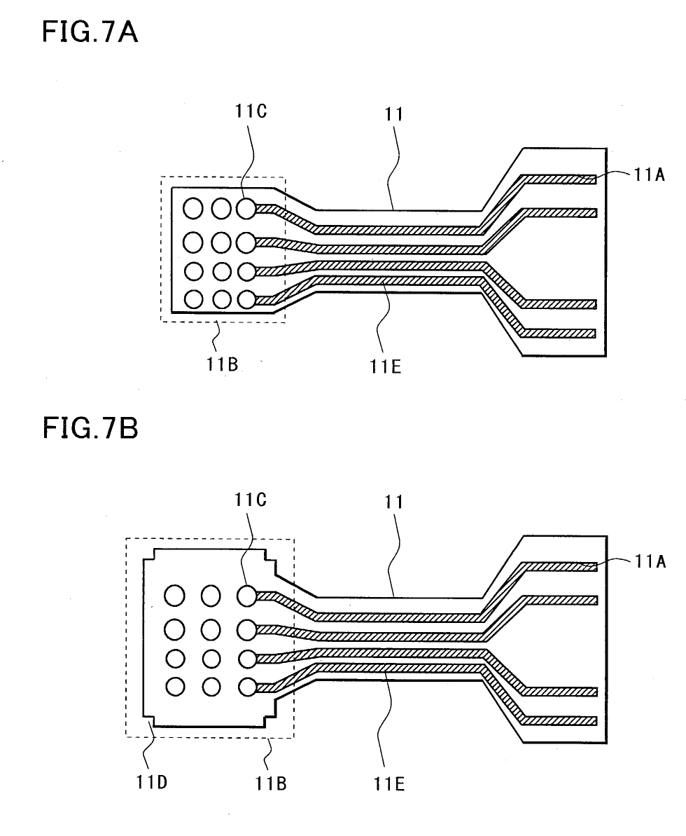

Details of the flexible sheet 11 will be described with reference to FIG. 7A and FIG. 7B. FIG. 7A is a plan view showing the flexible sheet 11 applied to the camera module shown in FIG. 1A through FIG. 1C, and FIG. 7B is a plan view showing the flexible sheet 11 applied to the camera module 10 shown in FIG. 2A and FIG. 2B.

Referring to FIG. 7A, the mount portion 11B on which CCD 15, etc., are mounted is formed at one end of the flexible sheet 11, and the connectors 11A as input/output terminals to the exterior are formed at the other end of the flexible sheet 11. Wires are formed on both surfaces of the flexible sheet 11 by electrical conductive paths 11E. In FIG. 7A, four electrical conductive paths 11E are illustrated, however, several dozens of electrical conductive paths 11E may be actually formed.

The mount portion 11B is formed at one end of the flexible sheet 11, and CCD 15, the peripheral elements 16 and the lens mount 12 are mounted on the surface of the one end of the flexible sheet 11. Accordingly, a plurality of connection electrodes 11C are formed on the surface of the flexible sheet 11 at the place where CCD 15 and the peripheral elements 16 will be mounted. The circuit device 20 is mounted on the back surface of the mount portion 11B through the external electrodes 25. Accordingly, a plurality of connection electrodes 11C are formed at positions corresponding to the positions of the external electrodes 25 of the circuit device 20.

The connectors 11A are electrodes formed at the other end of the flexible sheet 11, and electrically connected to the connection electrodes 11C through the electrical conductive paths 11E formed in the flexible sheet 11. The electrical conductive paths 11E are formed on both surfaces of the flexible sheet 11, however, the connectors 11A maybe formed on only the front surface of the flexible sheet 11. The electrical conductive paths 11E formed on the back surface of the flexible sheet 11 can be connected to the connectors 11A formed on the front surface of the flexible sheet 11 by leading out the electrical conductive paths 11E so that the electrical conductive paths 11E penetrate through the flexible sheet 11.

Since the conductive patterns 21 formed in the circuit device 20 mounted on the back surface of the mount portion 11B are formed by etching, the positions of the external electrodes 25 can be easily adjusted in conformity with the arrangement of the connectors 11A. Accordingly, as shown in FIG. 7A and FIG. 7B, the electrical conductive paths 11E formed in the flexible sheet 11 can be arranged nearly linearly. Accordingly, the places at which the electrical conductive paths 11E cross one another can be reduced, so that the number of wire layers of the flexible sheet 11 can be reduced.

The structure of the flexible sheet 11 applied to the camera module 10 shown in FIG. 2A and FIG. 2B will be described with reference to FIG. 7B. The basic structure of the flexible sheet 11 shown in FIG. 7B is the same as that shown in FIG. 7A, however a difference resides in that space portions 11D are formed.

Concretely, four space portions 11D are formed at the four corners of the mount portion 11B. The space portions 11D are areas where no flexible sheet is provided. The shape and position of each space portion 11D corresponds to the contact portion 12B equipped on the inner wall of the lens mount 12. Accordingly, in this embodiment, the space portions 11D each having a rectangular shape are equipped. Provision of the space portions 11D allow the circuit device 20 and the circuit device 20 to directly adhere to each other by adhesive agent with clearance being provided at the four corners of the flexible sheet 11.

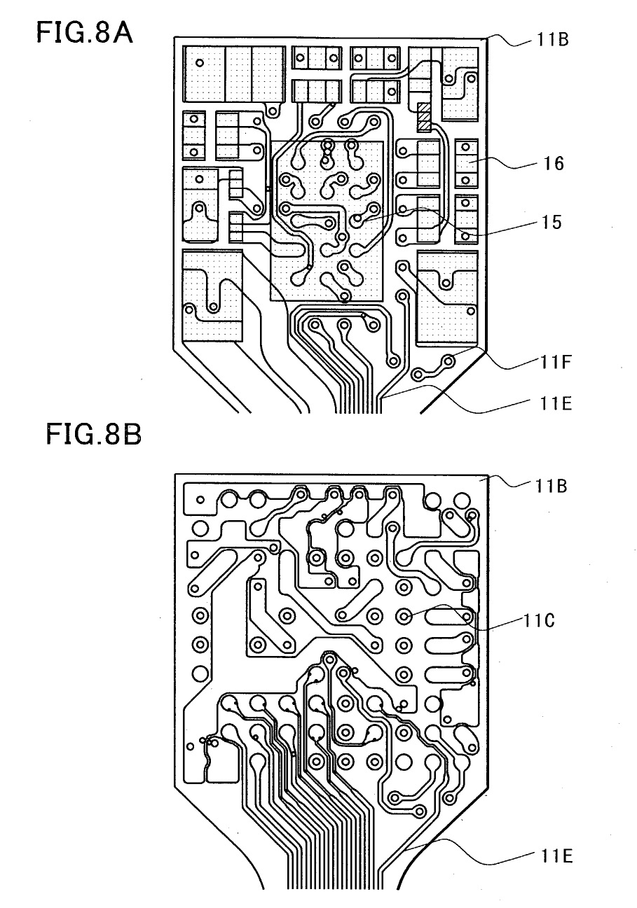

The specific structure of the electrical conductive paths 11E in the vicinity of the mount portion 11B of the flexible sheet 11 will be described with reference to FIG. 8A and FIG. 8B. FIG. 8A is a plan view showing the mount portion 11B of the surface (upper surface) on which CCD 15, etc., are mounted, and FIG. 8B is a plan view of the surface (lower surface) on which the circuit device 20 is mounted.

Referring to FIG. 8A, the electrical conductive paths 11E are formed on the front surface of the mount portion 11B. Pad portions for mounting CCD 15 and the peripheral elements 16 and wire portions are formed by the electrical conductive paths 11E. Furthermore, connecting portions 1F to be electrically connected to the electrical conductive paths 11E on the back surface are formed so as to penetrate through the flexible sheet 11. Referring to FIG. 8B, the electrical conductive paths 11E are formed on the back surface of the mount portion 11B, and the pad portions for mounting the circuit device 20 and the wire portions are formed. As described above, the electrical conductive paths 11E formed on the surface (i.e., the front surface) of the mount portion 11B are electrically connected to the electrical conductive paths 11E formed on the back surface of the mount portion 11B. Accordingly, CCD 15 and the peripheral elements 16 mounted on the surface of the mount portion 11B can be electrically connected to the circuit device 20 through the mount portion 11B.

In this invention, a plurality of circuit elements are installed in the circuit device 20, and, further, wires are formed in the circuit device, thereby constructing a predetermined electrical circuit. Accordingly, the layer structure of the mount portion 11B of the flexible sheet 11 and the structure of the electrical conductive paths can be simplified.

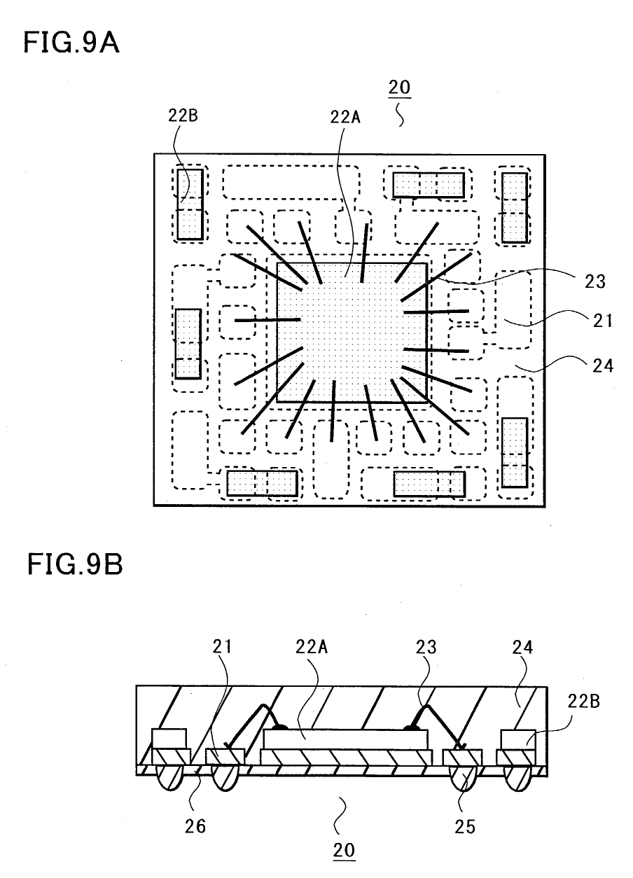

The structure of the circuit device 20 mounted on the back surface of the mount portion 11B of the flexible sheet 11 will be described with reference to FIG. 9A and FIG. 9B. FIG. 9A is a plan view of the circuit device 20, and FIG. 9B is a cross-sectional view of the circuit device 20.

The circuit device 20 mainly comprises the conductive patterns 21 for fixing the circuit elements 22, and insulating resin 24 which is coated on the circuit elements 22 and the conductive patterns 21 whose back surfaces are exposed, and supports the whole of the circuit device 20. The external electrodes 25 are formed on the back surface of the circuit device 20. Furthermore, resist 26 formed of resin covers places where no external electrode is formed in the back surface of the circuit device 20. The constituent elements of the circuit device 20 will be described hereunder.

The conductive patterns 21 are formed of metal such as copper, and the back surfaces thereof are exposed and embedded in the insulating resin 24. In this embodiment, the conductive patterns 21 constitute die pads on which the circuit elements 22 are mounted, bonding pads for fixing thin metal wires 23 and wires. Plating film of silver or the like is formed at the portions serving as the pads.

The circuit elements 22 are fixed to the conductive patterns 21 through brazing material such as solder. In this case, the semiconductor element 22A as the circuit element 22 is fixed to the conductive patterns 21 formed at the center portion, and the semiconductor device 22A and the conductive patterns 21 are electrically connected to each other through the thin metal wires 23. The semiconductor device 22A is electrically connected to CCD 15 fixed on the surface of the flexible sheet 11 through the wires formed in the flexible sheet 11. The chip elements 22B such as the resistors, the capacitors, and the diodes, are fixed to the conductive patterns 21 formed at the peripheral portion of the flexible sheet 11. The semiconductor device 22A maybe mounted face down on the conductive patterns 21. Furthermore, a bypass capacitor may be used as a chip element 22B. This allows the bypass capacitor and the semiconductor device 22A to be connected to each other through the thin metal wires 23 and the conductive patterns 21 at the shortest distance, so that power supply to the semiconductor device 22A can be stably performed.

Here, there is a case where DSP is mounted as a circuit element 22 in addition to the semiconductor device 22A. When DSP is used, DSP and the semiconductor 22A are electrically connected to each other in the circuit device 20. DSP and CCD 15 are connected to each other through the flexible sheet 11, and a digital signal transmitted from CCD 15 is quickly processed by DSP. A driver and DSP may be formed in one semiconductor device. In this case, the semiconductor device having the driver and DSP formed therein is mounted on the conductive patterns 21.

The back surfaces of the conductive patterns 21 are exposed and sealed by the insulating resin 24. In this embodiment, the circuit element 22, the thin metal wires 23 and the conductive patterns 21 are sealed by the insulating resin 24. The material of the insulating resin 24 may be thermosetting resin formed by transfer molding, thermoplastic resin formed by injection molding or the like. The upper surface of the insulating resin 24 is formed to be flat as shown in FIG. 9B.

As described above, the circuit device 20 has a mono-layered wiring structure based on the conductive patterns 21, however, a multi-layered wire structure may be formed inside the circuit device 20. When the multi-layered wire structure is formed, several layers of conductive patterns are laminated through insulating layers, and the respective conductive patterns are electrically connected to one another through via holes formed in the insulating layers. The circuit element is mounted on the conductive patterns 21 of the uppermost layer, and the external electrodes 25 are formed on the back surfaces of the conductive patterns 21 of the lowermost layer.

Furthermore, in the foregoing description, CCD 15 is used as the image pickup device, however, a CMOS sensor may be used in place of CCD 15. When the CMOS sensor is used as the image pickup device, DSP and the semiconductor device 22A are unnecessary. Accordingly, a semiconductor device having other functions may be installed in the circuit device 20. Concretely, a semiconductor device having an image compressing function (in conformity with MPEG4 or the like) or an interface function of USB may be used as the circuit element to be installed in the circuit device 20.

Still furthermore, in the foregoing description, a flat package having other shapes such as CSP may be used in place of the circuit device 20. Concretely, in the circuit device 20 mounted on the back surface of the mount portion 11B of the flexible sheet 11, the conductive patterns 21 are embedded in the insulating resin 24. Accordingly, as compared with CSP or the like, the circuit device 20 may be designed as a thin type which does not require any mount board or the like. Here, when a flat package such as CSP is used in place of the circuit device 20, the overall thickness of the camera module 10 is increased, however, substantially the same structure can be implemented.

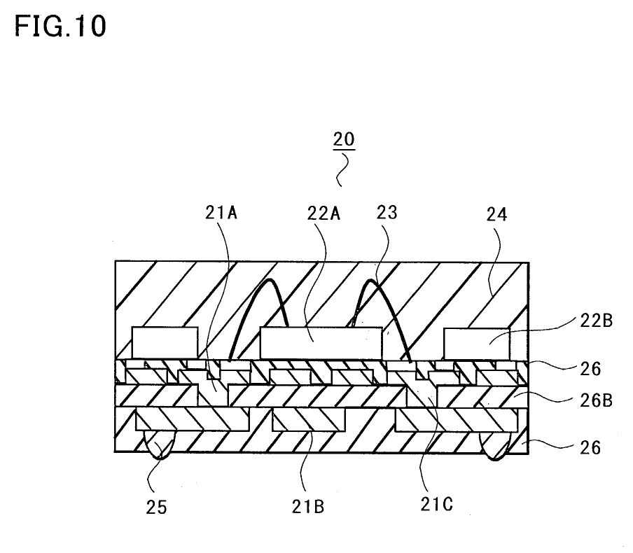

The structure of the circuit device 20 having a multi-layered wire structure will be described with reference to FIG. 10. In the following description, the circuit device having a two-layer wire structure will be described, however, a wire structure of two or more layers may be formed.

In this embodiment, a conductive pattern is constructed by a first conductive pattern 21A and a second conductive pattern 21B. The first conductive pattern 21A and the second conductive pattern 21B are formed through an insulating layer 26B in a multi-layer structure, and they are electrically connected to each other at desired places by multi-layered connection portions 21C.

The first conductive pattern 21A of the upper layer forms a connection area for the semiconductor device 22A and the chip element 22B as a passive element, and further constitutes a wire portion for forming a desired electrical circuit. Furthermore, the first conductive pattern 21A may be coated by resist 26, and the first conductive pattern 21A is exposed at a desired place.

The second conductive pattern of the lower layer constitutes pad portions on which the external electrodes 25 are formed. The second conductive pattern 21B may be coated by the resist 26 except the places where the external electrodes 25 are formed.

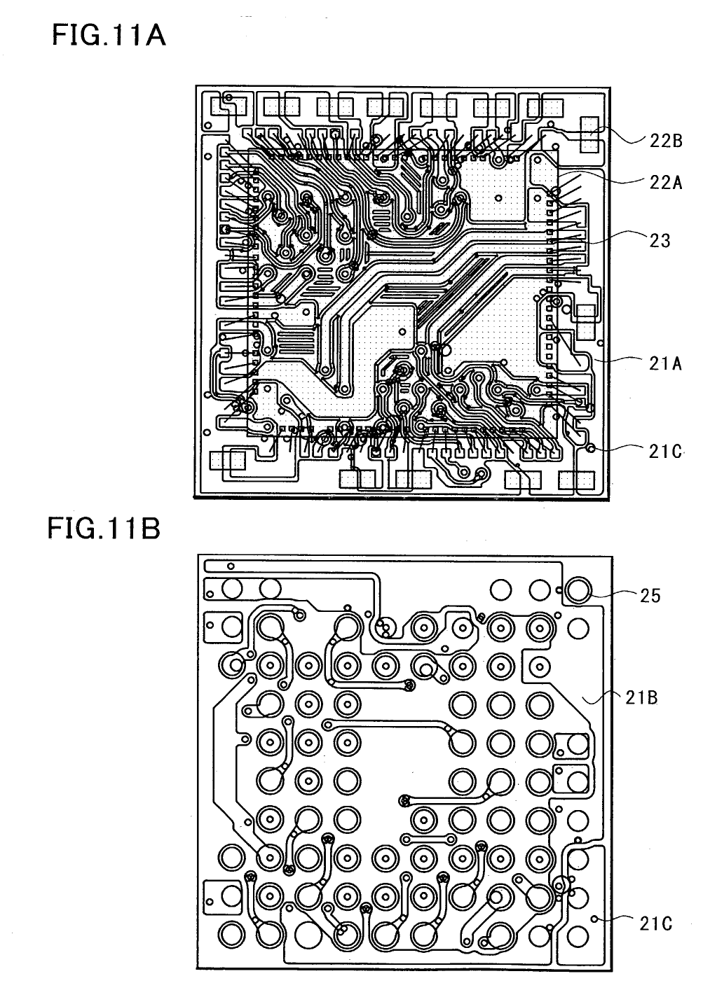

The structure of the first conductive pattern 21A and the second conductive pattern 21B will be described with reference to FIG. 11A and FIG. 11B. FIG. 11A is a plan view showing the first conductive pattern 21A, and FIG. 11B is a plan view showing the second conductive pattern 21B.

Referring to FIG. 11A, the first conductive pattern 21A forms the area serving as the bonding pads of the thin metal wires 23 around the semiconductor device 22A, and forms a mount area for the chip elements 22B at the peripheral portion thereof. The semiconductor device 22A and the first conductive pattern 21A are insulated from each other by the resist 26, so that thin wire portions comprising the first conductive pattern 21A are formed below the semiconductor device 22A. Furthermore, a multi-layered connection portion 21C to be connected to the second conductive pattern 21B of the lower layer is formed. Accordingly, the wire portions for connecting the bonding pads to one another, the wire portions for connecting the bonding pads to the multi-layered connecting portion 2lC, the wire portions for connecting the bonding pads to the mount area of the chip elements 22B, etc., are formed of the first conductive pattern 21A. The pattern connected to the ground potential may be constructed by the first conductive pattern 21A. The first conductive pattern 21A is designed in a fine structure, and thus it can be adapted for multiple-pin design and narrow-pitch design of the semiconductor device 22A.

Referring to FIG. 11B, the second conductive pattern 21B constitutes the pads on which the external electrodes 25 are formed. Wire portions for connecting the multi-layered connecting portion 21C to the pad portions may be formed.

The feature of the present invention resides in that the back surface of the mount face of CCD 15 is designed to be flat. Concretely, referring to FIG. 1C, CCD 15 and the lens 14 are mounted on the surface of the mount portion 11B of the flexible sheet 11, and the circuit device 20 is mounted on the back surface of the mount portion 11B. Furthermore, the insulating resin 24 is designed to be flat on the surface of the circuit device 20 which faces the surface where the conductive patterns 21 are exposed from the insulating resin 24. Accordingly, the surface of the flatly-formed insulating resin 24 may be used as a mount face of the camera module 10. For example, the camera module 10 can be fixed only by adhesion of the flat surface of the insulating resin 24 to the inside of the digital camera housing via the adhesive agent.

Furthermore, the present invention is characterized in that the function of the camera module 10 can be easily altered by fixing the positions of the external electrodes 25 of the circuit device 20 and preparing a plurality of kinds of circuit devices 20 which have different functions from one another. Concretely, two kinds of circuit devices, that is, a circuit device 20 having a standard image pickup function and a circuit device 20 having an image compression function in addition to the image pickup function are prepared. The former or latter circuit device 20 is selectively mounted on the flexible sheet 11 in accordance with a required function level of the camera module 10. With this structure, the cameral modules 10 whose function levels are substantially different from one another may be constructed by selectively mounting each of the circuit devices 20 whose functions are different from one another.

This is also applicable to CCD 15. That is, the connection electrodes 11C of the flexible sheet 11 on which CCD 15 is mounted are fixed, and several kinds of CCDs 15 which are different in pixel number and sensitivity are prepared. Accordingly, by merely selecting the most appropriate of the CCDs 15 in accordance with a required specification, the required specification can be implemented.

Furthermore, the present invention is characterized in that the layer structure of the circuit device 20 and the layer structure of the flexible sheet 11 can be designed to be unified. Concretely, the circuit device 20 and the flexible sheet 11 can be designed so as to construct a multi-layered wire structure. Therefore, in consideration of optimization of elements or optimization of the layer structure, both layer structures can be designed to be unified. It is possible to implement a design based on price or ease in production, for example, by setting the layer structure of the circuit device 20 to a two-layer structure and also setting the layer structure of the flexible sheet 11 to a two-layer structure. This can also optimize the arrangement of the peripheral elements, etc., mounted on the surface of the flexible sheet 11.

Still furthermore, the present invention is characterized in that even when the arrangement of the connectors 11A formed at the end portion of the flexible sheet 11 is required to be altered, the requirement can be satisfied by merely changing the layer structure of the flexible sheet 11. Concretely, as described above, with respect to the circuit device 20 mounted at the end portion of the flexible sheet 11, the positions of the external electrodes 25 thereof can be easily changed. Accordingly, the number of places at which the wires cross each other can be reduced in the layer structure of the flexible sheet 11, and thus the layer structure of the flexible sheet 11 is further simplified as compared with the prior art. Accordingly, the requirement of the arrangement of the connectors 11A can be satisfied by merely changing the layer structure of the flexible sheet flexibly.

Still furthermore, the present invention is characterized in that the rigidity of the mount portion 11B is enhanced by mounting the circuit device 20 on the back surface of the mount portion 11B of the flexible sheet 11. That is, the circuit device 20 supports the mount portion 11B from the back surface, and the position of CCD 15 mounted on the surface of the mount portion 11B can be fixed.

(Second Embodiment Describing Camera Module Manufacturing Method)

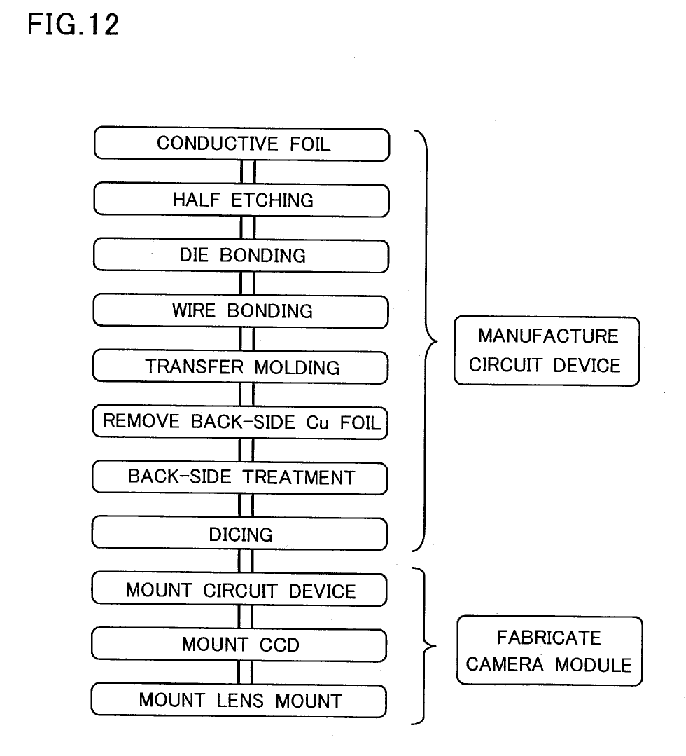

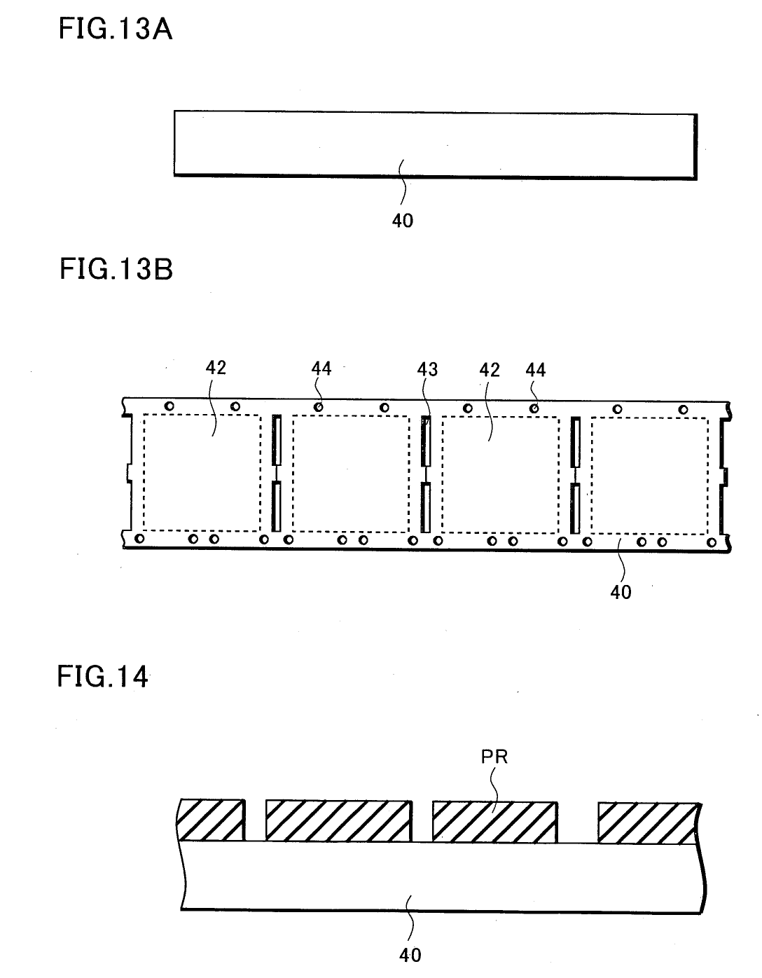

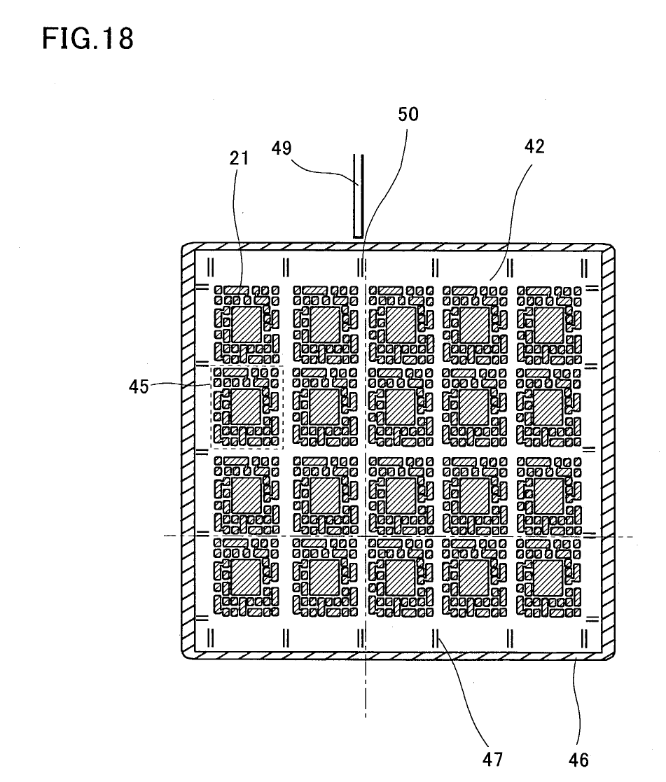

The camera module 10 according to the present invention is manufactured by the following process. That is, referring to the flowchart of FIG. 12, the circuit device 20 is manufactured by the steps of; preparing conductive foil 40; forming separation grooves 41 on the conductive foil 40 so that the separation grooves 41 are shallower than the thickness of the conductive foil 40, thereby forming conductive patterns 21; fixing the circuit elements 22 to each circuit device portion 45 of a desired conductive pattern 21; wire-bonding the circuit elements 22 and the desired conductive pattern 21; carrying out common molding so that the circuit elements 22 of each circuit device portion 45 are collectively coated with insulating resin 24 and the separation grooves 41 are filled with the insulating resin 24; removing the back surface of the conductive foil 40 so that the insulating resin 24 is exposed; and dicing the insulating resin 24 into circuit device portions. Thereafter, the circuit device 20 is mounted on the back surface of the flexible sheet 11, and CCD 15, the lens mount 12, etc., are mounted on the front surface of the flexible sheet 11, thereby manufacturing the camera module 10. The respective steps of the present invention will be described hereunder with reference to FIG. 13 through FIG. 19.

As shown in FIG. 13 through FIG. 15, a first step of the present invention prepares a conductive foil 40, and forms separation grooves 41 shallower than the conductive foil 40 on the conductive foil 40 by half etching, thereby forming conductive patterns 21.

In this step, as shown in FIG. 13A, a sheet-shaped conductive foil 40 is prepared. The material of the conductive foil 40 is selected in consideration of adhesive property, bonding property and plating property of brazing material. As a material, conductive foil containing Cu may be used as a main material, conductive foil containing Al as a main material, and a conductive foil formed of an alloy of Fe—Ni or the like.

The thickness of the conductive foil 40 is preferably set to approximately 10 μm to 300 μm in consideration of subsequent etching, however, it may be basically set to 300 μm or more, or to 10 μm or less. As described later, it is only required that the separation grooves 41 are formed to be shallower than the thickness of the conductive foil 40. The sheet-like conductive foil 40 is prepared in the form of a roll having a predetermined width, for example, 45 mm. This roll maybe fed to each step described later, or the roll may be cut into strip-shaped pieces of the conductive foil 40 each of which is fed to each step described later.

Concretely, as shown in FIG. 13B, four to five blocks 42 each of which has many circuit devices 45 formed on the strip-shaped foil 40 are arranged at a distance. A slit 43 is formed between the respective blocks 42 to absorb the stress of the conductive foil 40 which is caused due to a heat treatment in the molding step or the like. Index holes 44 are formed at a constant interval at the upper and lower peripheral edges of the conductive foil 40, and used for positioning in each step. Subsequently, the conductive patterns are formed.

First, as shown in FIG. 14, a photoresist (etching-resistant mask) PR is formed on the conductive foil 40, and the photoresist PR is subjected to patterning so as to expose the conductive foil 40 from which the area serving as the conductive patterns 21 is excluded. Thereafter, the conductive foil 40 is selectively etched.

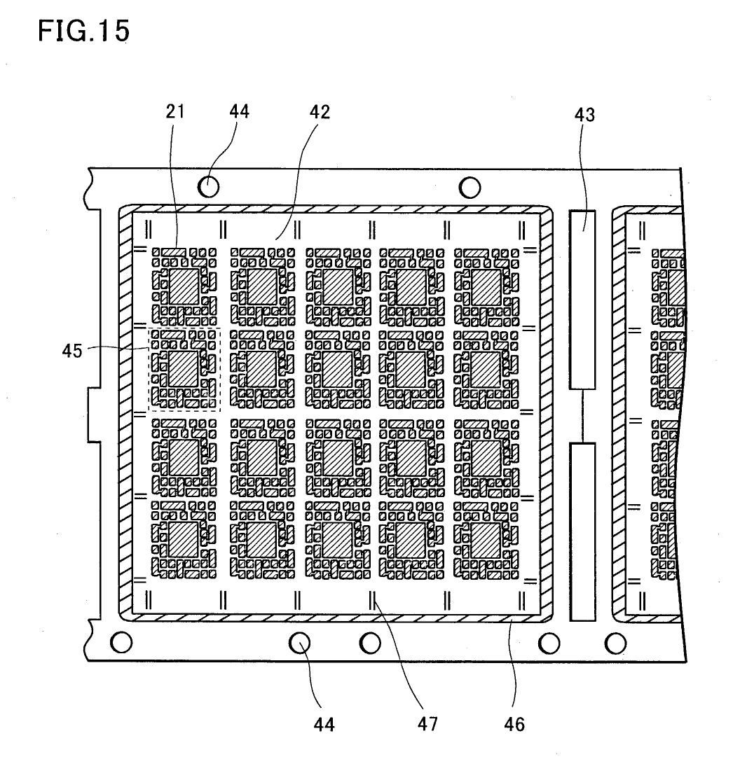

FIG. 15 shows the specific conductive pattern 21. This figure corresponds to the enlarged view of one block 42 shown in FIG. 13B. One portion surrounded by a dotted line represents one circuit device portion 45, and many circuit device portions 45 are arranged in a matrix form of 4 columns×4 rows, and the same conductive patterns 21 are formed for every circuit device portion 45. A frame-like pattern 46 is formed on the periphery of each block, and positioning marks 47 for dicing are formed inside the frame-like pattern 46 so as to be slightly spaced from the frame-like pattern 46. The frame-like pattern 46 is used for engagement with a metal mold, and acts to reinforce the insulating resin 24 after the back surface of the conductive foil 40 is etched.

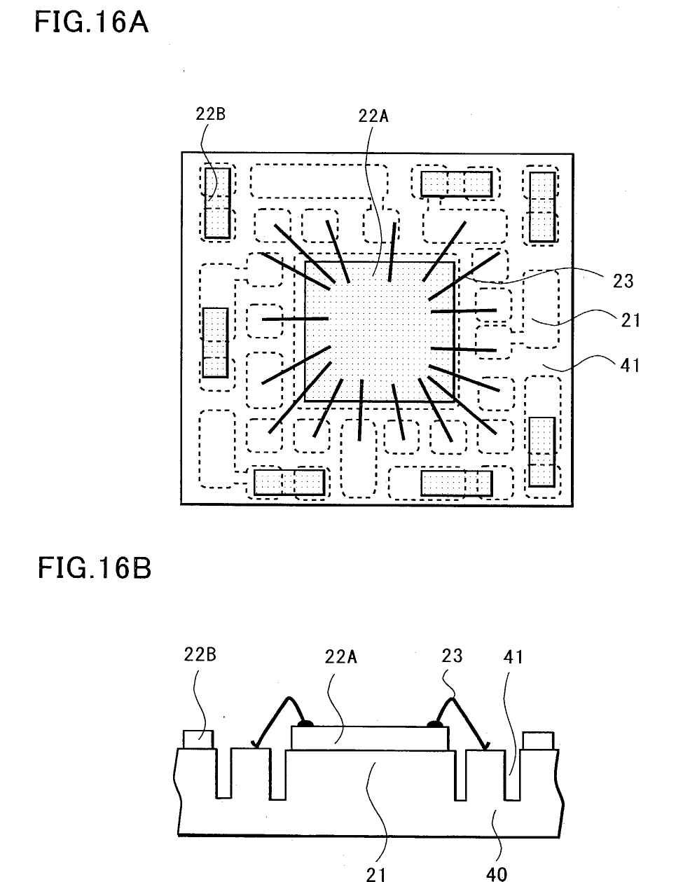

A second step of the present invention is to fix the circuit elements 22 to each circuit device portion 45 of a desired conductive pattern 21 as shown in FIG. 16A and FIG. 16 Band bond the electrodes of the circuit elements 22 to the desired conductive pattern 21 through wires. FIG. 16A is a plan view showing one circuit device portion, and FIG. 16B is a cross-sectional view of the circuit device portion.

Here, the semiconductor device 22A and the peripheral elements 22B as the circuit elements 22 are die-bonded to the conductive patterns 21. Thereafter, the electrodes of the semiconductor device 22A of each circuit device portion are collectively wire-bonded to one another by ball bonding based on thermo-compression and by wedge bonding based on ultrasonic waves. Concretely, the semiconductor device 22A is mounted on the conductive patterns 21 at the center portion by brazing material, and the electrodes of the semiconductor device 22A and the conductive patterns 21 are electrically connected to each other through the thin metal wires 23. Furthermore, the peripheral elements 22B are mounted on the conductive patterns 21 formed at the peripheral portion of the circuit device portion through brazing material such as solder. In the foregoing description, only the semiconductor device 22A is mounted as the semiconductor device at the center portion, however, DSP or the like may be mounted in addition to the semiconductor device 22A.

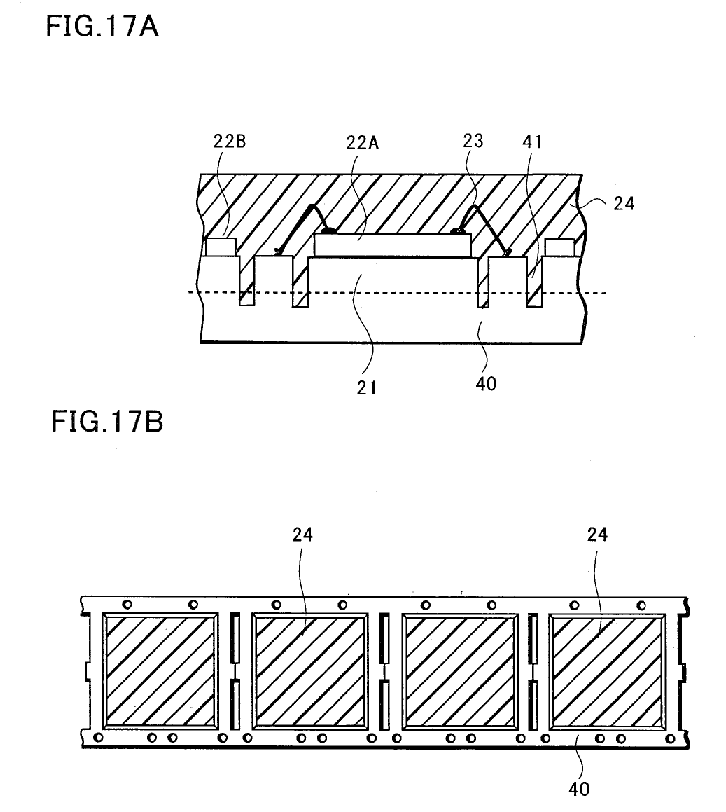

A third step of the present invention is to carry out the common molding with insulating resin 24 so that the circuit elements 22 of each circuit device portion 45 are collectively coated by the insulating resin 24 and the separation grooves 41 are filled with the insulating resin 24 as shown in FIG. 17A and FIG. 17B.

In this step, as shown in FIG. 17A, the insulating resin 24 perfectly coats the circuit elements 22 and the plural conductive patterns 21, and also the insulating resin 24 is filled in the separation grooves 41 to be firmly joined to the separation grooves 41. Furthermore, the conductive patterns 21 are supported by the insulating resin 24.

Furthermore, this step can be implemented by transfer molding, injection molding or potting. Thermosetting resin such as epoxy resin may be used as the resin material in the case of the transfer molding, and thermoplastic resin such as polyimide resin, polyphenylene sulfide may be used in the case of injection molding.

When the transfer molding or the injection molding is carried out in this step, each block 42 is achieved by accommodating the circuit device portions 45 in one common metal mold and then carrying out the common molding with one insulating resin 24 every block. Therefore, the amount of resin can be greatly reduced as compared with the method for molding each circuit device portion individually like the conventional transfer molding or the like.

This step is characterized in that the conductive foil 40 serving as the conductive patterns 21 acts as a support board until the insulating resin 24 is coated. In the prior art, a support board which is not originally required is used to form the conductive patterns. However, according to the present invention, the conductive foil 40 serving as the support board is an indispensable material as the material of the electrodes. Therefore, an advantage that the process can be performed while omitting the constituent materials as much as possible is achieved, and costs can be also reduced.

The separation grooves 41 are formed to be shallower than the thickness of the conductive foil, and thus the conductive foil 40 is not separated into individual pieces as the conductive patterns 21. Accordingly, the conductive foil 40 can be handled as a single sheet-like body, and when the insulating resin 24 is molded, the work of feeding the conductive foil 40 to the metal mold and mounting the conductive foil 40 in the metal mold can be very easily performed.

The fourth step of the present invention is to remove the back surface of the conductive foil 40 until the insulating resin is exposed.

In this step, the back surface of the conductive foil 40 is chemically and/or physically removed, and separated as conductive patterns 21. This step is carried out by polishing, grinding, etching, metal vaporization based on laser or the like. The whole surface of the conductive foil 40 is subjected to wet etching to expose the insulating resin 24 from the separation grooves 41. The surface thus exposed is represented by a dotted line in FIG. 17A. As a result, the conductive foil 40 is separated into pieces as the conductive patterns 21.

As a result, such a structure where the back surfaces of the conductive patterns 21 are exposed can be achieved. That is, the surface of the insulating resin 24 filled in the separation grooves 41 and the surfaces of the conductive patterns 21 are substantially coincident with each other. Accordingly, since the circuit device of the present invention is not equipped with any step which has been provided for the conventional back-side electrodes, it is directly horizontally shifted and self-aligned by surface tension of solder when mounted.

Furthermore, the back surfaces of the conductive patterns 21 are treated, and the final structure shown in FIG. 9A and FIG. 9B is achieved. That is, the conductive patterns 21 which are exposed as occasion demands are coated with conductive material such as solder, and the circuit device 20 is completed.

The fifth step of the present invention is to separate the insulating resin 24 for every circuit device portion 45 by dicing.

In this step, the block 42 is suctioned onto the mount table of a dicing device under vacuum, and the insulating resin 24 of the separation grooves 41 is diced into individual circuit devices along each dicing line (chain line) between the respective circuit device portions 45 by a dicing blade 49.

In this step, it is preferable that the dicing blade 49 is operated at such a cutting depth that the insulating resin 24 can be substantially cut out, and the block 42 is subjected to a chocolate breaking process by a roller after the block 42 is picked up from the dicing device. In the dicing operation, the positioning marks 47 of each block which are formed in the first step in advance are recognized, and the dicing is carried out on the basis of the positioning marks 47. As well known, the dicing is carried out as follows. That is, all the dicing lines are diced in the longitudinal direction, the mount table is rotated by 90 degrees and then the dicing is carried out along the dicing lines 70 in the lateral direction.

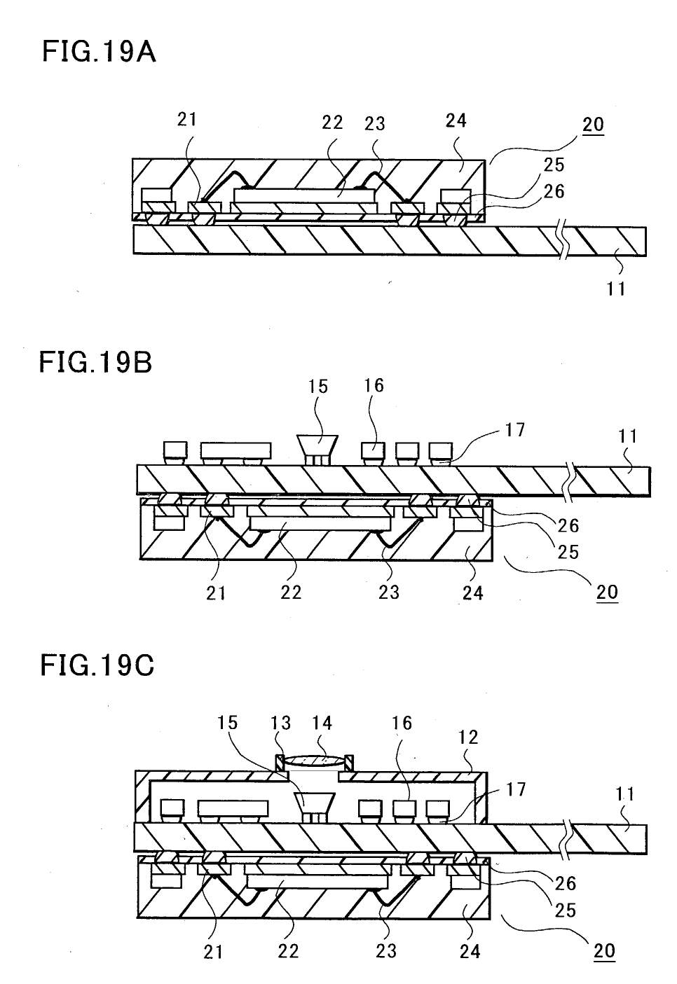

The sixth step of the present invention is to mount the circuit device 20, etc., manufactured in the preceding step on the flexible sheet 11 as shown in FIG. 19A through FIG. 19C to there by manufacture the camera module 10. FIG. 19A through FIG. 19C are cross-sectional views showing the respective steps to manufacture the camera module 10.

The circuit device 20 is mounted on the mount portion of the flexible sheet 11 as shown in FIG. 19A. The external electrodes 25 formed of solder are formed on the back surface of the circuit device, and the connecting electrodes 11C are formed at places corresponding to the external electrodes 25 on the mount portion of the flexible sheet 11. Accordingly, the mounting work of the circuit device 20 can be performed in a reflow step. Furthermore, the mount portion 11B comprising the flexible sheet 11 is reinforced by the circuit device 20 by mounting the circuit device 20 on the mount portion 11B.

As shown in FIG. 19B, the flexible sheet 11 is inverted and the surface thereof on which the circuit device 20 is mounted is placed face down. CCD 15 and the peripheral elements 16 are mounted through the brazing material such as solder on the surface of the mount portion of the flexible sheet 11 on which the circuit device 20 is not mounted. Here, diodes, resistors, capacitors, coils, etc., which serve as noise-countermeasure elements are used as the peripheral elements 16.

As described above, the flexible sheet 11 is originally formed of flexible material, and thus it runs short of rigidity as the mount board. Accordingly, in the present invention, the rigidity of the mount portion 11B is enhanced by mounting the circuit device 20 on the back surface of the mount portion 11B of the flexible sheet 11. That is, the circuit device 20 is used as a seat which receives pressure when CCD 15, etc., are mounted. The mounting of the circuit device 20 on the back surface of the mount portion 11B prevents the mounting precision from being reduced due to partial sinking of the mount portion 11B when CCD 15, etc., are mounted.

As shown in FIG. 19C, the lens mount 12 is fixed to the flexible sheet 11 so as to cover the CCD 15 and the peripheral elements 16 mounted on the surface of the flexible sheet 11. The lens 14 is equipped through the lens barrel 13 at the upper portion of the lens mount 12. The two-dimensional position of the lens 14 accurately corresponds to the position of CCD 15 located below the lens 14. The mounting of the lens mount 12 onto the flexible sheet 11 can be carried out via insulating adhesive agent. Here, when reflow of solder can be applied to the lens mount 12, the lens mount 12 can be mounted on the flexible sheet 11 simultaneously with CCD 15.

The camera module 10 is manufactured by the steps described above. The mount portion of the flexible sheet 11, the circuit device 20 and the lens mount 12 are formed to have substantially the same two-dimensional size. Accordingly, the camera module 10 has a structure having no projecting portion. Therefore, the mounting of the camera module 10 into the housing in the subsequent steps can be easily performed by adhesive agent or the like.

The foregoing description is made of the method for manufacturing the circuit device 20 having the mono-layer conductive patterns 21. However, a multi-layered circuit device may be manufactured by the steps described above. When a multi-layered circuit device 20 is manufactured, a step of forming conductive patterns in a multi-layered structure through insulating layers is needed in addition to the above steps. The respective layers are electrically connected to one another through via holes or the like.

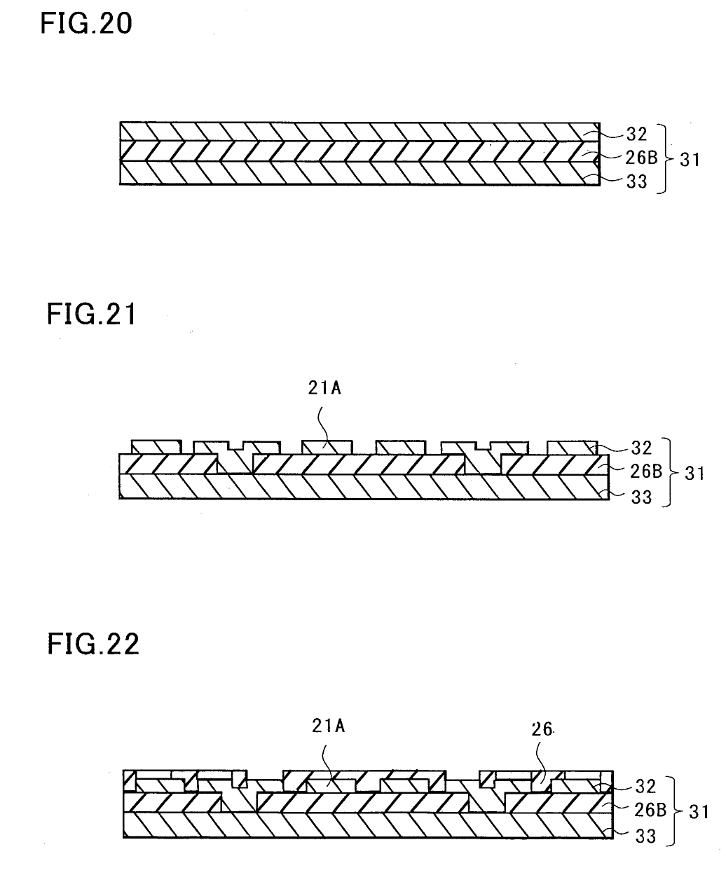

Next, the method for manufacturing the circuit device 20 having the multi-layered structure will be described with reference to FIG. 20 through FIG. 25. The process after the circuit device 20 is manufactured is the same as described above.

As shown in FIG. 20, an insulating sheet 31 comprising a first conductive film 32 and a second conductive film 33 which are laminated through an insulating layer 26B is prepared. The first conductive film 32 is thinly formed because it forms minute conductive patterns on which a circuit device is mounted, and the second conductive film 33 is thickly formed in consideration of strength because it serves to mechanically support the insulating sheet 31.

Subsequently, the first conductive patterns 21A are formed by selectively etching the first conductive film 32 as shown in FIG. 21. Furthermore, the first conductive patterns 21A at desired places and the insulating layer 26B there under are partially removed to form through holes, and a plating film is formed at these places to electrically connect the first conductive patterns 21A to the second conductive film 33.

Subsequently, the first conductive patterns 21A are coated with resist 26 as shown in FIG. 22, and the resist 26 is partially removed so as to expose the first conductive patterns 21A at places where the thin metal wires are bonded and the chip elements are mounted.

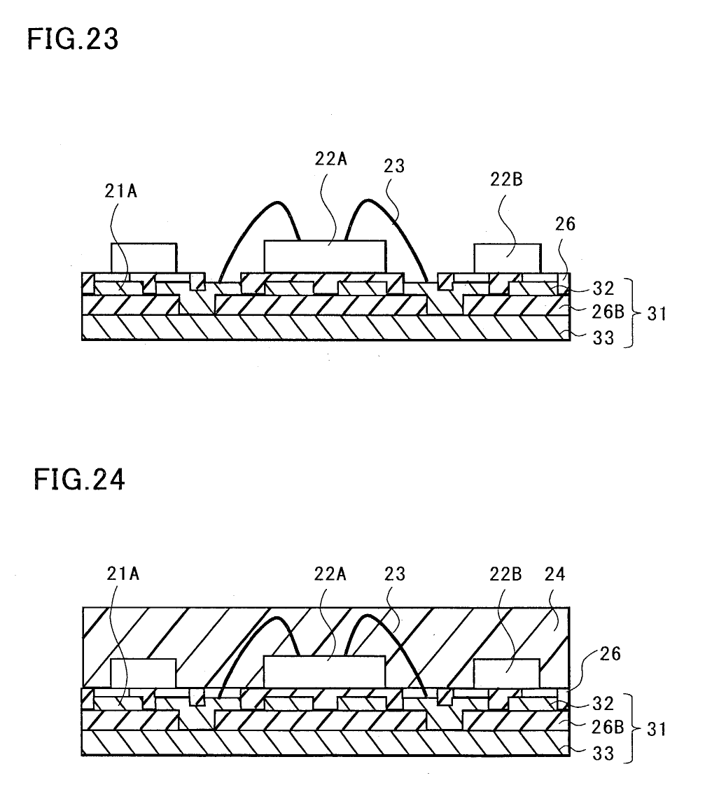

Subsequently, the semiconductor device 22A and the chip elements 22B are mounted as shown in FIG. 23. The semiconductor device 22A is fixed to the upper portion of the resist 26 via insulating adhesive agent or the like, and electrically connected to the first conductive patterns 21A through the thin metal wires 23. The chip elements 22B are fixed to the first conductive patterns 21A through brazing materials such as solder.

As shown in FIG. 24, the circuit device mounted on the first conductive patterns 21A are coated and sealed by the insulating resin 24. This sealing can be performed by transfer molding using thermosetting resin or injection molding using thermoplastic resin. Accordingly, the overall circuit device is supported by the insulating resin 24.

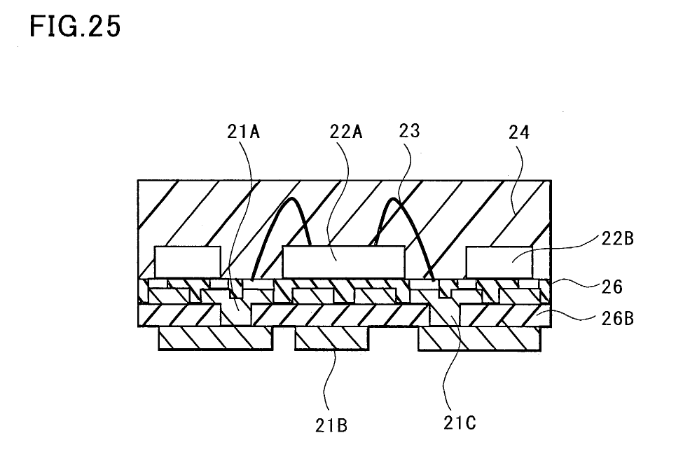

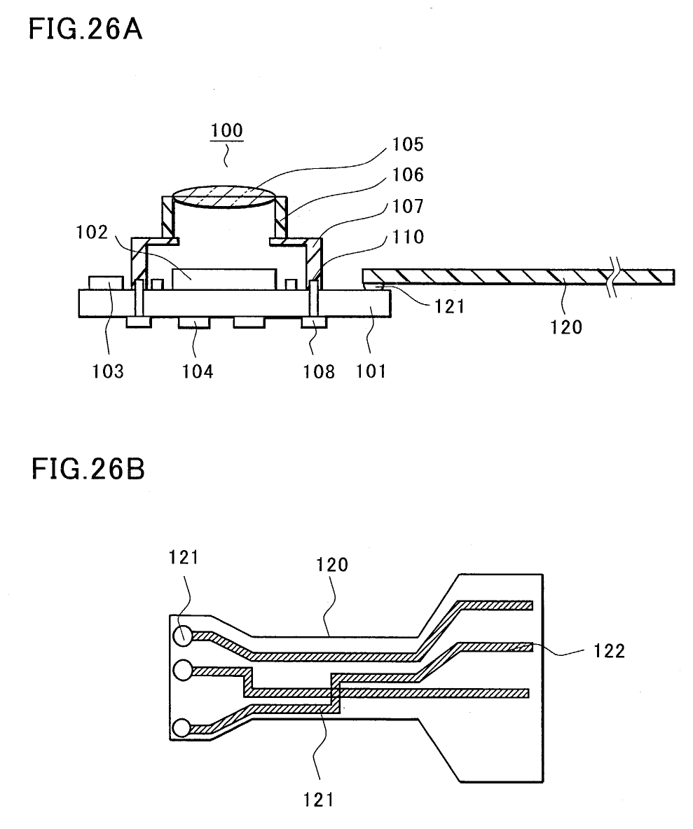

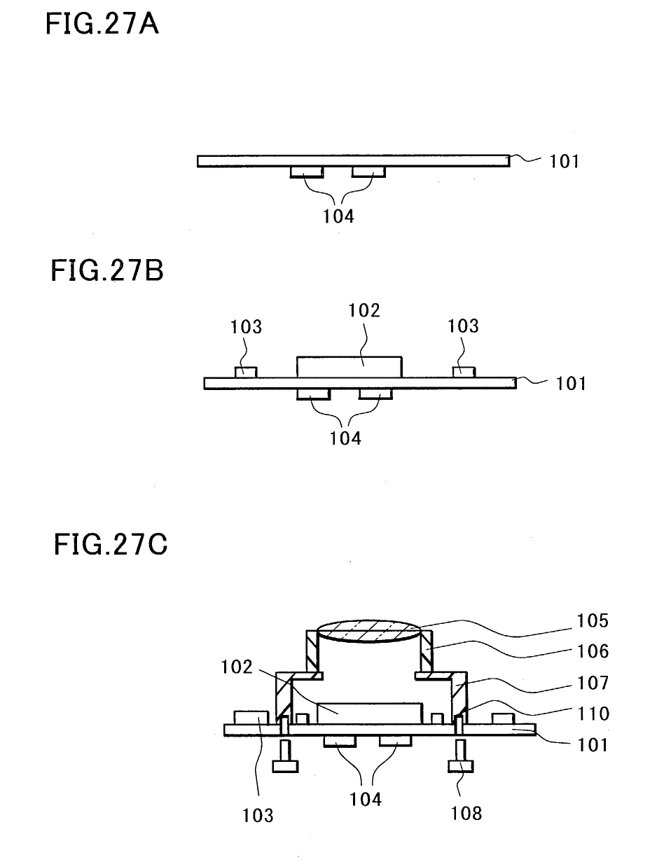

As shown in FIG. 25, the second conductive film 33 is partially removed to form the second conductive patterns 21B. Furthermore, the second conductive patterns 21B are coated by resist 26, and then external electrodes are formed. For example, a circuit device as shown in FIG. 10 is manufactured by the above steps. Subsequent steps are the same as the steps shown in FIG. 19A through FIG. 19C.

What is claimed is:

1. A camera module, comprising:
a resin sheet having electrical conductive paths on both surfaces thereof; a lens mount provided on the surface of the resin sheet; a circuit device mounted on the back surface of the resin sheet; an image pickup device housed in the lens mount; and a lens fixed to the upper portion of the lens mount, wherein the circuit device contains a semiconductor element electrically connected to the image pickup device and a passive element.

2. The camera module according to claim 1, wherein the circuit device has conductive patterns for fixing circuit elements, the back surfaces of the conductive patterns being exposed, and insulating resin for coating on the circuit elements and the conductive patterns and supporting the whole of the circuit device.

3. The camera module according to claim 1, wherein the circuit device has a multi-layered wire structure.

4. The camera module according to claim 1, wherein the resin sheet is equipped with connectors at one end portion thereof, and a mount portion having the same size as the circuit device at the other end portion thereof, and the lens mount is mounted on the surface of the mount portion while the circuit device is mounted on the back surface of the mount portion.

5. The camera module according to claim 1, wherein the insulating resin on the surface opposite to the surface of the circuit device from which external electrodes are exposed is designed to be flat.

6. The camera module according to claim 1, wherein a semiconductor device installed in the circuit device is a driver IC or DSP for driving the image pickup device.

7. The camera module according to claim 1, wherein peripheral elements are mounted on the surface of the resin sheet.

8. The camera module according to claim 7, wherein the image pickup device and the peripheral elements are covered by the lens mount.

9. The camera module according to claim 7, wherein the peripheral elements are capacitors, resistors or coils as countermeasures to noises.

10. The camera module according to claim 1, wherein the image pickup device comprises CCD or CMOS.

11. The camera module according to claim 1, wherein the lens mount covers the resin sheet and the side surface of the circuit device.

12. The camera module according to claim 1, wherein the image pickup device is fixed to the electrical conductive paths formed on the surface of the resin sheet.

13. The camera module according to claim 1, wherein an opening portion is formed in the resin sheet at a place where the circuit device is mounted, and the image pickup device is mounted on conductive patterns of the circuit device exposed from the opening portion.

14. A method for manufacturing a camera module, comprising the steps of:
preparing a resin sheet having a mount portion formed at one end thereof, the mount portion having electrical conductive paths on both surfaces thereof;
mounting a circuit device on connection electrodes on the back surface of the mount portion;
mounting an image pickup device on connection electrodes on the surface of the mount portion; and
mounting a lens mount so as to cover the image pickup device.

15. The camera module manufacturing method according to claim 14, further comprising a step of forming contact portions at four corners of the opening portion of the lens mount, and a step of making the contact portions directly adhere to the four corners of the circuit device via adhesive agent.

16. The camera module manufacturing method according to claim 14, wherein peripheral elements as countermeasures to noises are mounted on the surface of the mount portion.

17. The camera module manufacturing method according to claim 14, wherein the image pickup device is mounted after the mount portion is reinforced by mounting the circuit device on the mount portion.
